(19) United States
(12) Patent Application Publication
(10) Pub. No.: US 2025/0140663 A1
(43) Pub. Date: May 1, 2025

(54) POWER MODULE WITH A CIRCUIT CARRIER

(71) Applicant: Robert Bosch GmbH, Stuttgart (DE)

(72) Inventor: Irfan Aydogmus, Nuertingen (DE)

(21) Appl. No.: 18/921,556

(22) Filed: Oct. 21, 2024

(30) Foreign Application Priority Data
Oct. 26, 2023 (DE) 10 2023 210 595.0

(51) Int. Cl. H01L 23/498; H01L 23/00; H01L 23/31; H01L 23/367; H01L 23/522; H01L 23/538

(52) U.S. Cl. CPC H01L 23/49811; H01L 23/3121; H01L 23/367; H01L 23/49844; H01L 23/5227; H01L 23/5381; H01L 23/5386; H01L 23/5389; H01L 24/48; H01L 2224/4814; H01L 2924/13055; H01L 2924/13091; H01L 2924/30107

(57) ABSTRACT

A power module with a circuit carrier. The circuit carrier includes a carrier substrate and an electrical insulation layer. The circuit carrier has a first conductor structure with an external contact region and at least one second conductor structure with at least one external contact region and a further, third conductor structure which includes at least one external contact region. Semiconductor components are arranged on the circuit carrier individually or in groups. Current-conducting components T+ bridge and T− bridge are arranged in a multifunctional frame assigned to the power module, which components are electrically connected to the semiconductor components installed in the power module individually or in groups by at least one solder connection by including a spacer.

### FIELD

The present invention relates to a power module with a circuit carrier comprising a carrier substrate and an electrical insulation layer. The circuit carrier has a first conductor structure with an external contact region, at least one second conductor structure with at least one external contact region, and a further, third conductor structure which comprises at least one external contact region.

### BACKGROUND INFORMATION

In the related art, power modules, which are installed in a power module bridge, for example, are additionally molded. During molding, the power module is embedded in a solid protective housing, for example made of plastic (molding compound). The molding compound is used to enclose and protect the interior of the power module. However, these enclosures of the power module by means of molding compound are not particularly resistant to cracks.

German Patent Application No. DE 11 2017 004 390 T5 describes a power module that has the following features: an insulating substrate with a front side to which a power semiconductor element is fastened; a base plate connected to a rear side of the insulating substrate; a housing fastened to the base plate and surrounding the insulating substrate; a cover fastened to the housing and forming a sealed region; and a silicone gel serving as a filling element which fills the entire sealed region and has an internal stress that acts as a compressive stress.

German Patent No. DE 10 2014 219 998 B4 describes a power module, in particular for providing a phase current for an electric motor. The power module comprises a circuit carrier having a surface, at least two first contact faces on the surface, and at least two first power transistors, which each have a ground contact face. In each case, a first power transistor of the at least two first power transistors is arranged directly on one of the first contact faces and is electrically conductively connected directly to the corresponding first contact face via its ground contact face. In addition, the power module comprises a second contact face on the surface and at least two second power transistors, which each have a ground contact face. The at least two second power transistors are arranged directly on the second contact face and are electrically conductively connected directly to the second contact face via their respective ground contact faces. Furthermore, the power module comprises at least two third contact faces on the surface, wherein the at least two second power transistors each have a further contact face on their sides facing away from the surface of the circuit carrier, and in each case a second power transistor of the at least two second power transistors is electrically conductively connected via its further contact face to one of the at least two third contact faces in each case. The at least two first contact faces and the at least two third contact faces are arranged alternately one after the other in a longitudinal direction of the power module, and the second contact face is arranged next to the at least two first contact faces and the at least two third contact faces, wherein the second contact face has at least two contact regions, wherein in each case one of the at least two contact regions is located next to one of the at least two first power transistors. The at least two first power transistors each have a further contact face on their sides facing away from the surface of the circuit carrier, and in each case a first power transistor of the at least two first power transistors is electrically conductively connected via its further contact face to the in each case one contact region, located next to it, of the at least two contact regions of the second contact face. In this case, the at least two contact regions of the second contact face and the at least two second power transistors are arranged alternately one after the other in the longitudinal direction.

European Patent No. EP 2 418 925 B1 describes an electrical contacting between a flexible film, which has at least one conductor track, and at least one electrical contact of a sensor device or control device. In this case, an end portion of the flexible film is electrically contacted by heat input at a contact point, wherein the end portion of the flexible film is placed against protruding electrical contacts at the contact point. The end portion of the flexible film is designed with a breaking wave shape, in particular as a deflection.

### SUMMARY

According to an example embodiment of the present invention, a power module is provided with a circuit carrier which comprises a carrier substrate and an electrical insulation layer, wherein the circuit carrier comprises a first conductor structure with an external contact region and at least one second conductor structure with at least one external contact region, and a further, third conductor structure which has at least one external contact region, wherein semiconductor components are arranged individually or in groups. In a multifunctional frame assigned to the power module, contact faces are arranged which are electrically connected to semiconductor components installed individually or in groups in the power module by at least one solder connection with the inclusion of at least one spacer.

In a further advantageous embodiment of the power module provided according to the present invention, the semiconductor components are arranged individually or in groups on a base or base surface of the power module.

The power module provided according to the present invention is made such that the first spacer is arranged in the region of a joint between a bottom side of the multifunctional frame and a top side of the power module. Component differences or manufacturing differences that arise when joining the components in question can be compensated for via the at least one spacer provided within the at least one solder connection. In a further advantageous embodiment of the power module proposed according to the present invention, current-conducting paths, such as a T+ bridge and/or a T− bridge and/or a phase bridge, are arranged one above the other or next to one another in the multifunctional frame, whereby a low-inductance connection is advantageously achieved.

In a further advantageous embodiment of the power module provided according to the present invention, a first materially bonded connection is formed within an opening on the bottom side of the multifunctional frame. This results in relatively easy access to the at least one materially bonded solder connection.

In a further advantageous example embodiment of the power module provided according to the present invention, the second spacer is arranged directly on a contact face of the semiconductor component.

In the power module provided according to an example embodiment of the present invention, there is a second solder connection located between the first spacer and the second spacer.

The power module provided according to an example embodiment of the present invention is further characterized in that the first and the second solder connection contain a first and a second solder layer, respectively.

In a further advantageous embodiment of the power module provided according to the present invention, this module is preferably connected to a cooling surface either via a sintered layer or via a solder/adhesive connection.

It is provided that the power module provided according to an example embodiment of the present invention is designed in such a way that the semiconductor components and the second spacers connected to them via contact faces are enclosed by a molding compound. The molding compound, which in particular surrounds the semiconductor components, can effectively improve their protection against environmental influences, such as temperature, vibrations, or liquid wetting and the like.

In the power module provided according to an example embodiment of the present invention, a multifunctional frame and a power module are decoupled from one another and are electrically contacted substantially in the Z direction via materially bonded connections, which are preferably formed as solder connections. Advantageously, current-conducting contact faces run in the multifunctional frame, which frame can be arranged above or below the power module, while the semiconductor components arranged individually or in groups on a bottom surface of the power module are located in the power module. This module in turn is cooled by a cooling surface, wherein the cooling surface, which dissipates heat and is preferably flat, is connected to the bottom side of the power module either via a sintered connection or via a soldered or adhesive connection. The multifunctional frame can be arranged both above and below the power module in the Z direction; the position of the cooling surface is determined accordingly in such a way that cooling always takes place where the greatest heat loss occurs, i.e. at the bottom of the power module; i.e. the cooling surface is thermally connected.

The materially bonded connection provided according to the present invention between the multifunctional frame and the semiconductor component accommodated at the bottom of the power module, for example MOSFETS, IGBTs, or diodes, or another electronic component, can create an effective and robust electrical connection between the multifunctional frame, the contact faces that extend there, and the semiconductor component itself. Preferably, in the materially bonded connections, which are preferably designed as solder connections, spacers are arranged either in an angular or in a circular or disk-shaped configuration. The spacers can be used to compensate for height differences. Furthermore, the spacers offer an enlarged surface so that a current-conducting electrical connection can be formed on the one hand, but the height can be made extremely low.

The solution provided according to the present invention enables improved cooling to be achieved, since larger distances between the semiconductor components can be realized. This creates the possibility of relocating current-conducting paths, such as T+ bridges and/or T-bridges as well as a phase bridge from the power module, into the multifunctional frame and arranging them there on top of each other or next to each other with low inductance. This has the advantage that the magnetic fields that form in the bridges when current is conducted cancel each other out and parasitic currents are avoided. The low-inductance connection achieved in this way can significantly reduce switching losses.

The decoupling of the first and second levels in the power module and multifunctional frame results in a compact design of the power module provided according to the present invention. Furthermore, the selected, superimposed arrangement of the two functional levels, namely the first level in which the semiconductor elements are arranged and the second level in which the current is conducted, can substantially improve production. More favorable tolerances can be achieved for more precise further processing, and the service life of the power module is increased because complexity is reduced. In particular, if the contacting of the semiconductor components takes place in the first level and that of the current-conducting components takes place in the second level, i.e. within the multifunctional frame, a robust electrical conduction option for the aforementioned components is achieved. Furthermore, the design of press-in pins is technically proven and they can be robustly produced on a large scale.

By means of the solution proposed according to the present invention, the external contact regions can advantageously be relocated from the power module into a multifunctional frame arranged offset therefrom in the Z direction. Further following the solution proposed according to the present invention, the bottom side of the power module can advantageously be connected to the top side of a cooling surface either by a flat sintered connection or by a flat solder connection or by a flat adhesive connection. All embodiments offer the advantage of flat contacting, which allows the waste heat generated during operation of the semiconductor components of the power module to be reliably dissipated, and temperature overload of the power module is avoided.

### BRIEF DESCRIPTION OF THE DRAWINGS

The present invention is described in more detail below with reference to the figures.

FIG. 1 shows a plan view of a first circuit carrier of a power module comprising a carrier substrate and a possible arrangement of semiconductor components, according to an example embodiment of the present invention.

FIG. 2 shows a plan view of a power module with separate cooling and layout areas with laterally arranged regions for press-in pins, according to an example embodiment of the present invention.

FIG. 3 shows an arrangement of a power module mounted on a cooling surface and a multi-function frame arranged above it in the Z direction, according to an example embodiment of the present invention.

FIG. 4 shows an exploded view of the components accommodated in the multifunctional frame, according to an example embodiment of the present invention.

FIG. 5 shows a plan view of the arrangement according to FIG. 3, according to an example embodiment of the present invention.

FIG. 6 shows a detailed representation, reproduced on an enlarged scale, of an electrical connection between the multifunctional frame on the one hand and the semiconductor component on the base of the power module on the other hand, according to an example embodiment of the present invention.

FIG. 7 shows an enlarged view of a solder connection, according to an example embodiment of the present invention.

FIG. 8 shows a perspective partial section through the multifunctional frame, according to an example embodiment of the present invention.

FIG. 9 shows a side view of the joined arrangements of the components in the multifunctional frame and the power module, according to an example embodiment of the present invention.

FIG. 10 shows vertical guides of T+ bridges and T-bridges, according to an example embodiment of the present invention.

### DETAILED DESCRIPTION OF EXAMPLE EMBODIMENT

In the following description of the embodiments of the present invention, identical or similar elements are denoted by the same reference signs, a repeated description of these elements in individual cases being dispensed with. The drawings show the subject matter of the present invention only schematically.

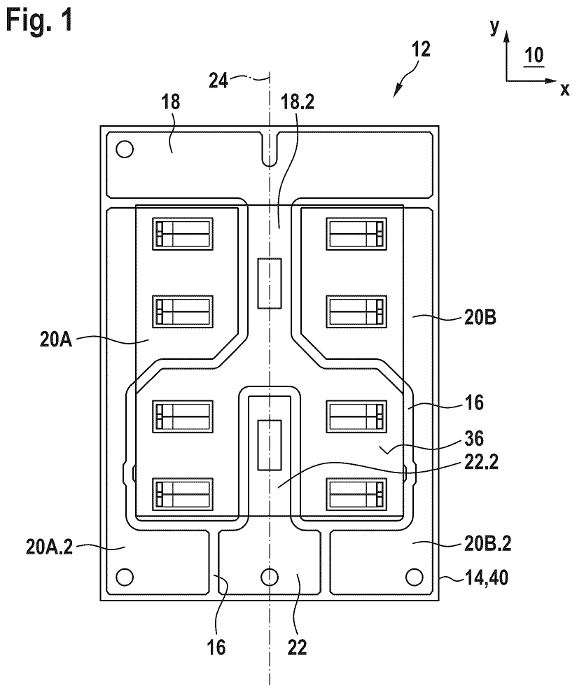

FIG. 1 shows a plan view of a power module 12, in particular of its circuit carrier 14.

From the top view according to FIG. 1, it can be seen that a carrier substrate 40 of the circuit carrier 14 is provided with a number of conductor structures 18, 20A, 20B, 22. The circuit carrier 14 extends in an X, Y plane 10, wherein the circuit carrier 14 is provided with an electrical insulation layer 16. On this layer, separated from each other by channel-shaped interruptions, there is a first conductor structure 18 which has an external contact region 18.2. Furthermore, second conductor structures 20A, 20B are located opposite one another on the first circuit carrier 14, symmetrically to a central longitudinal axis 24 of the power module 12. Each of the two second conductor structures 20A, 20B comprises an external contact region 20A.2, 20B.2. Finally, a third conductor structure 22, which has at least one external contact region 22.2, is applied to the circuit carrier 14 or to its electrical insulation layer 16.

The aforementioned conductor structures 18, 20A, 20B, 22 are electrically separated from one another and are applied to the circuit carrier 14 substantially symmetrically to the central longitudinal axis 24. Position 36 designates an active surface, and a layout surface, flowing around it, for the current routing is designated by reference sign 38. As the carrier substrate 40 of the circuit carrier 14, AMB (active metal brazing, (OFC (oxygen-free copper)/Si₃N₄/OFC)) is preferably selected.

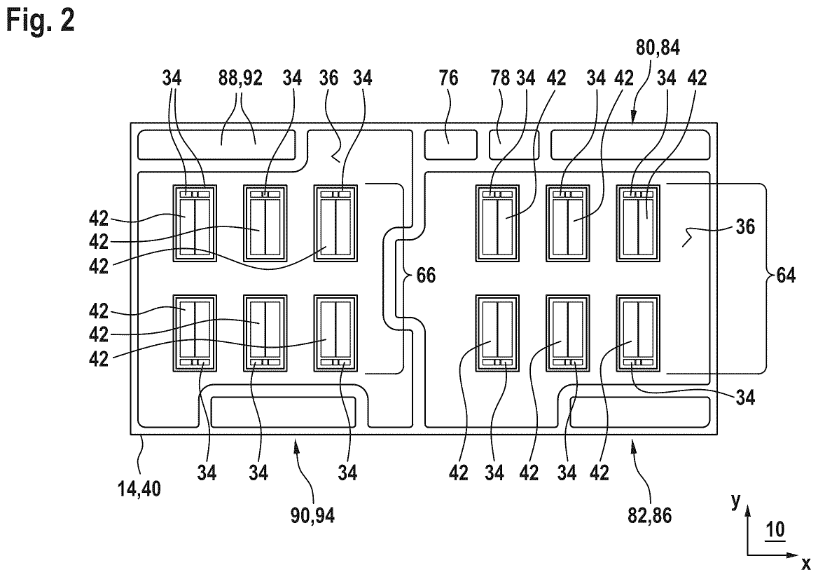

The illustration according to FIG. 2 shows a plan view of the power module 12, wherein in this schematic illustration semiconductor components 42 are arranged on active surfaces 36, which components may be for example transistors, MOSFETS, IGBTS, diodes or other semiconductor components that can be used as semiconductor switches. FIG. 2 shows that a first group 64 of semiconductor components 42 is accommodated on the active surfaces 36. The individual semiconductor components 42 can be designed, for example, as MOSFETs and have control terminals 34 on their outer sides, via which a controlling (not shown in more detail) of the individual semiconductor components 42 of the first group 64 of semiconductor components 42 can take place. Analogous to the first group 64, a second group 66 of semiconductor components 42 is arranged, which can also be MOSFETs, on the outer region of each of which control terminals 34 are formed. An arrangement of the semiconductor components 42 in groups 64, 66 is not absolutely necessary-depending on the scaling, these can also be arranged individually, i.e. not in groups. The semiconductor components 42 of the second group 66 of semiconductor components can be controlled from the outside via the control connections 34, although this is not shown in more detail in the illustration in FIG. 2.

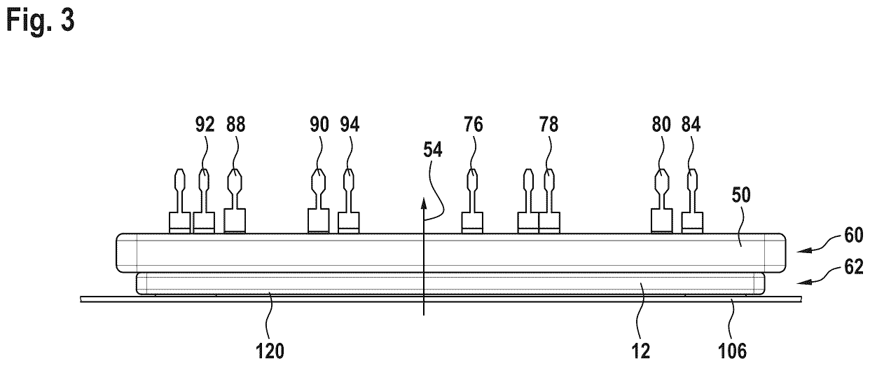

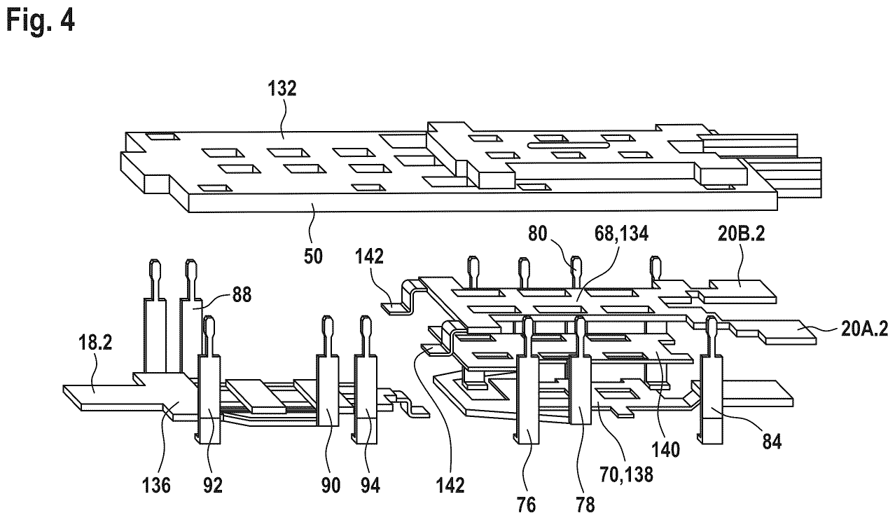

Furthermore, it can be seen from the plan view according to FIG. 2 that in the X, Y plane 10 shown in FIG. 2, regions are provided on the longitudinal sides of the circuit carrier 14 in the form of a carrier substrate 40, in which regions press-in pins 76-94 protrude into the plane of the drawing according to FIG. 2. Specifically, these are first and second press-in pins 76, 78 as well as third and fourth press-in pins 80, 82 and, arranged opposite one another, fifth and sixth press-in pins 84, 86. In the region of the opposite end face of the circuit carrier 14, seventh and eighth press-in pins 88, 90 are provided, as well as ninth and tenth press-in pins 92, 94. The spatial arrangement of the press-in pins 76, 78, 80, 82, 84, 86, 88, 90, 92, 94 can be seen in more detail in the illustrations in FIGS. 3 and 4.

In the side view according to FIG. 3, it can be seen that a power module 12, shown here from the outside, is received with its bottom side 120 on a cooling surface 106. Viewed in the Z direction 54, a multifunctional frame 50 is located above the power module 12. On the top side of the multifunctional frame 50 shown from the side in FIG. 3, the individual press-in pins 76, 78, 80, 82, 84, 86, 88, 90, 92, 94—here lying in a drawing plane-protrude vertically upwards. The press-in pins 76-94 allow the components arranged within the multifunctional frame 50 or the power module 12 arranged underneath to be electrically contacted in a robust and simple manner. From the illustration according to FIG. 3, it is further apparent that the multifunctional frame 50 represents a first level 60, while the power module 12 arranged beneath it in this case forms a second level 62. Likewise, in a modification of the illustration according to FIG. 3, the multifunctional frame 50 could be arranged above the power module 12, seen in the Z direction 54.

The illustration in FIG. 4 shows an exploded view of the components contained in the multifunctional frame 50.

FIG. 4 shows that the phase bridge 136 can be electrically contacted via the seventh and eighth contact pins 88, 90. Furthermore, FIG. 4 shows that in this embodiment a T+ bridge 134 (first contact face 68) and a second T− bridge 138 (second contact face 70) are arranged one above the other. Between these there is an insulation layer 140, which can be made of paper, cardboard or the like. The T+ bridge 134 also has contact strips 142 that lead to a cooling connection 150, as described below. Both components T+ bridge 134 and T− bridge 138 are preferably arranged at a minimal distance above or next to each other so that the magnetic fields that arise when current flows cancel each other out. The smaller the distance between the T+ bridge 134 and the T− bridge 138 can be kept, the more complete a mutual cancellation of the magnetic fields can be achieved. The press-in pins 76, 78, 80, 84 are used for the electrical contacting of semiconductor components or for signal transmission and/or for the contacting of the semiconductor components 42 arranged in the power module 12 situated thereunder.

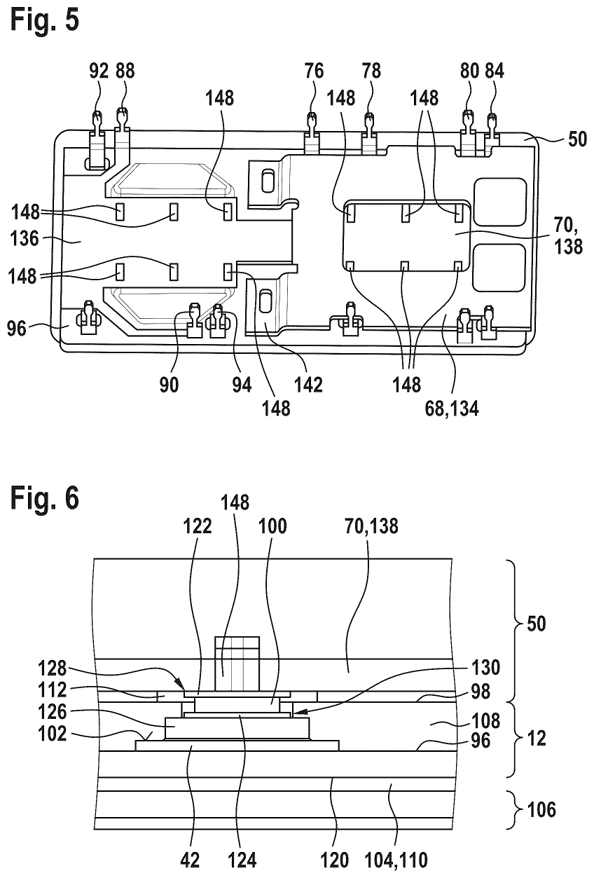

From the illustration in FIG. 5, it can be seen that the T+ bridge 134 (first contact face 68) is accommodated in the multifunctional frame 50 above the power module 12. The press-in pins 76, 78, 80, 84 surrounding the T+ bridge 134 are installed in such a way that they electrically contact semiconductor components 42 arranged individually or in groups 64, 66 below the T+ bridge 134, preferably on a base 96 of the power module 12. The semiconductor components 42 arranged on the base 96 of the power module 12 are semiconductor components 42, such as MOSFETS, IGBTs, diodes, which are used for example as semiconductor switches.

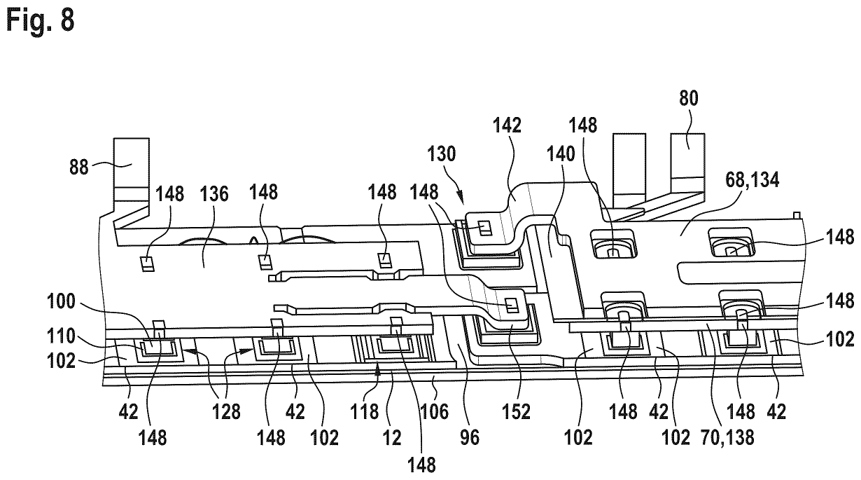

A T− bridge 138 (second contact face 70) shown in plan view in the arrangement according to FIG. 5 is electrically contacted for example via press-in pins 88, 90 directly connected to it. Furthermore, in the region of the T− bridge 138 (second contact face 70) as shown in FIG. 5, ninth and tenth press-in pins 92, 94 are provided via which semiconductor components 42 arranged individually or in groups 64, 66 below the T− bridge 138 (second contact face 70) are electrically contacted. FIG. 5 also shows the contact strips 142 extending downwards from the T+ bridge 134, which, as shown in FIG. 8, represent cooling connections 150, 152. In FIG. 5, compensation openings 148 are located in the phase bridge 136 and in the T− bridge 138, through which excess solder can escape or flow away during the soldering process, depending on the soldering process carried out.

The illustration in FIG. 6 shows, on an enlarged scale, a superimposed arrangement of multifunctional frame 50, power module 12, and cooling surface 106.

FIG. 6 shows that in this enlarged-scale illustration, the semiconductor components 42, which can be for example MOSFETs or other transistors, are accommodated on the base 96 of the power module 12. The bottom side 120 of the module is connected to the cooling surface 106 either via a flat sintered connection 104 or via a flat solder/adhesive connection 110. This arrangement option offers rapid heat dissipation of the semiconductor components 42 at the base 96 of the power module 12, since the waste heat generated during operation can be quickly dissipated so that the semiconductor components 42 are not exposed to excess temperatures.

The illustration according to FIG. 6 further shows that the electrical connection to the T+ bridges 134 and T-bridges 138 (not shown in detail in FIG. 6) in the multifunctional frame 50 is made by means of a first solder connection 128 and a further, second solder connection 130. The two solder connections 128, 130 comprise first and second solder layers 122, 124. Furthermore, a first spacer 100 and a second, disk-shaped spacer 126 are integrated into the solder connections 128, 130. Alternatively, it is also possible to omit one of the spacers 100, 126; in this case, the second solder connection 130 can be omitted.

The use of the first spacer 100 or the second spacer 126 advantageously enables the compensation of component tolerances or the compensation of tolerances arising from production when joining the multifunctional frame 50 to the power module 12. The current-conducting components of the multifunctional frame 50 are connected to the semiconductor components 42 of the power module 12 via the solder connections 128, 130, seen in the Z direction 54.

It can therefore be seen from FIG. 6 that the first solder connection 128, which preferably comprises a first solder layer 122, is formed in an opening 112 of the multifunctional frame 50. The first solder connection 128 connects this frame, or one of the T+ bridges 134, T-bridges 138, to the first spacer 100. The second solder connection 130 includes a second solder layer 124 and runs between the first spacer 100 and the top side of the disk-shaped second spacer 126. This spacer in turn is located on the contact face 102 on the top side of the semiconductor component 42.

By using the first and second spacers 100, 126, which can be formed in any geometry and at any height, component tolerances or manufacturing tolerances resulting from joining can be easily compensated, so that the height of the arrangement made up of the multifunctional frame 50, power module 12, and cooling surface 106 with the interposition of the sintered connection 104 or the solder/adhesive connection 110 does not increase and can be kept substantially constant. The spacers 100, 126 further prevent excessive heat input into the semiconductor component 42 during the joining process, i.e. in the present case during soldering.

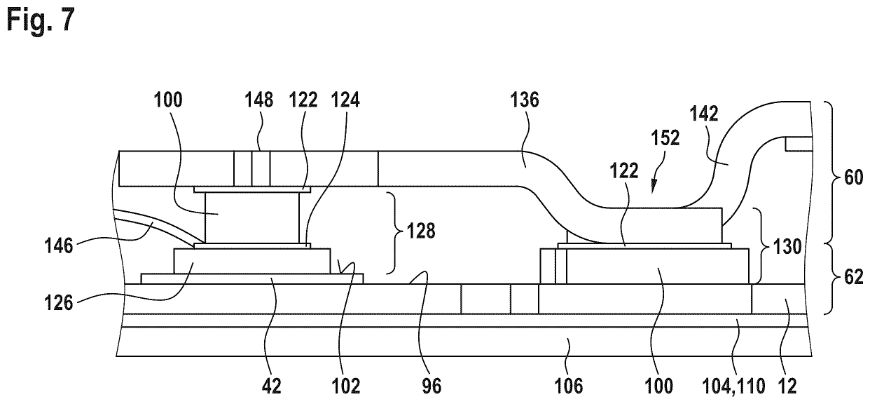

FIG. 7 shows an enlarged view of solder connections 128, 130.

The first solder connection 128 comprises a disk-shaped first spacer 100 and a further, second spacer 126. The first spacer 100 is attached to the bottom side of the phase bridge 136 by means of the first solder layer 122 and is materially bonded to the second spacer 126 by means of a second solder layer 124. This spacer in turn is attached to the contact face 102 of the semiconductor component 42. The arrangement of the spacers 100, 126 could also be reversed relative to the illustration in FIG. 7. In addition to compensating for tolerances, the spacers 100, 126 absorb the energy input acting on the semiconductor component 42 during the material-bond joining process, in this case during soldering, and equalize this energy input.

FIG. 7 further shows the second solder connection 130. This connection comprises the first solder layer 122, with which the first spacer 100 is joined to the bottom side of the phase bridge 136. The first spacer 100 is located on the bottom 96 of the power module 12, so that the heat of the phase bridge 136 can be dissipated through the bottom surface 96 via the sintered connection 104 or the solder/adhesive connection 110 to the cooling surface 106. The same holds for a further cooling connection 150 located in the drawing plane according to FIG. 4, via which the contact strip 142 of the T+ bridge 134 is connected in the same way to the base 96 of the power module 12 for heat dissipation.

It can be seen from the perspective partial section according to FIG. 8 that both the phase bridge 136 and the superimposed T+ bridges 134 (first contact face 68) and T− bridge 136 (second contact face 70), which are separated by the insulation layer 140, have compensation openings 148. These openings allow excess solder, for example, to escape from the first solder layer 122, so that no stresses develop within the solder connections 128, 130 or the cooling connections 150, 152. FIG. 8 also shows the contact strips 142 extending from the T+ bridge 134 (first contact face 68), which are connected, by cooling connections 150 with the interposition of the first spacer 100, to the base 96 of the power module 12 and to the cooling surface 106 connected thereto for heat dissipation. Between the phase bridge 136 and the bottom surface 96 are the solder connections 128, 130, shown only in simplified form in FIG. 8, between the phase bridge 136 and the semiconductor components 42 and between the T− bridge 138 and the semiconductor components 42, respectively. The insulation layer 140 can be a layer of paper or cardboard a few tenths of a millimeter thick. The smaller the distance between the T+ bridge 134 and the T− bridge 138 can be kept, the more complete a cancellation of the opposing magnetic fields can be achieved, so that a low-inductance connection is obtained which enables short switching times of the semiconductor components 42.

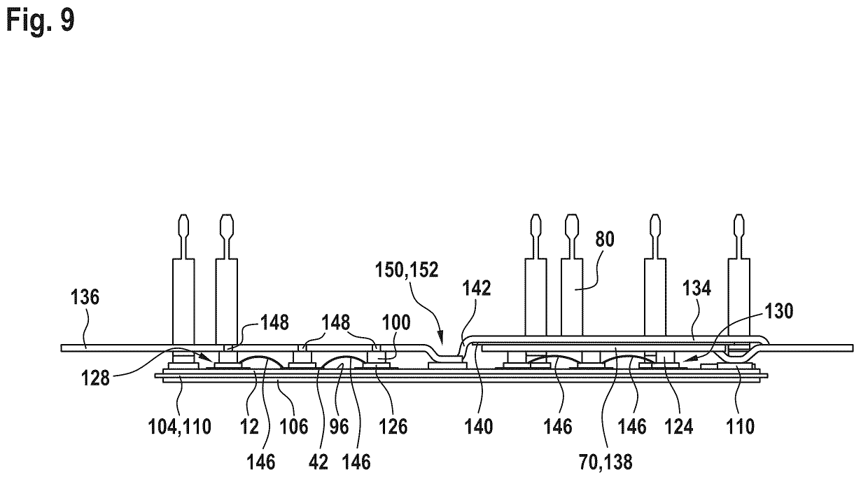

FIG. 9 shows a side view of the assembled arrangement of the components of the multifunctional frame 50 and the power module 12.

FIG. 9 shows the sequence of first solder connections 128 according to FIG. 7 between the bottom side of the phase bridge 136 and the base 96 of the power module 12. Furthermore, the side view according to FIG. 9 shows the T+ bridge 134 (first contact face 68), which is insulated by the insulation layer 140 from the T− bridge 138 under it (second contact face 70). The distance between the T+ bridge 134 and the T-bridge 138 is minimized, so that the magnetic fields that arise when current is conducted through them largely cancel each other out and a low-inductance connection is achieved. The second solder connections 130, as shown in FIG. 7 in an enlarged scale, run between the bottom side of the T− bridge 138 and the base 96 of the power module 12 according to FIG. 9. Approximately in the middle of the illustration according to FIG. 9 are the cooling connections 150, 152, which are arranged one behind the other in the plane of the drawing of FIG. 9. Furthermore, the side view according to FIG. 9 shows the course of bonding wires 146, both between the bottom side of the phase bridge 136 and the base surface 96 and between this base surface and the bottom side of the T− bridge 138 in the right part of FIG. 9. The bottom side of the power module 12 as shown in FIG. 9 is joined to the cooling surface 106 via the sintered layer 104 or the solder/adhesive connection 110, so that the heat generated during operation of the semiconductor components 42 which are arranged on the base 96 of the power module 12 can be quickly dissipated and stress on these components by excess temperature is excluded. Above the first solder connections 128 and above the second solder connections 130, the compensation openings 148 are made in the phase bridge 136 and also in the T− bridge 138, which openings allow excess solder material to escape so that the solder connections 128, 130 can be formed substantially stress-free.

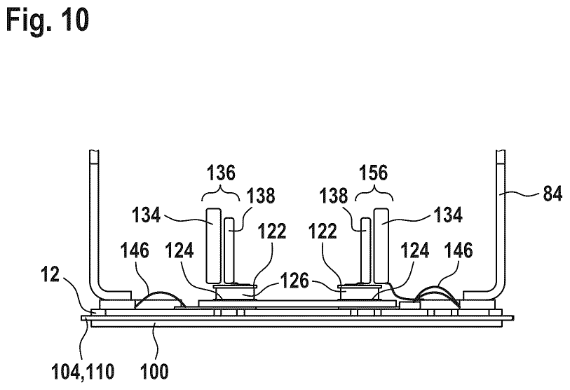

The illustration in FIG. 10 shows an embodiment in which a vertical guidance of current-conducting components, in particular the T+ bridge 134 and the T− bridge 138, is realized.

As can be seen from the view in FIG. 10, semiconductor components 42 are here electrically contacted, via second spacers 126, to the current-conducting components running above in vertical guide 156, in particular the T+ bridge 134 and the T− bridge 138 extending parallel thereto in the plane of the drawing according to FIG. 10. In this case, for example, in contrast to FIGS. 8 and 9, the T+ bridge 134 and the T-bridge 138 are positioned on edge relative to one another, wherein a minimum distance between the components mentioned is also ensured in the design of the vertical guide 156 according to FIG. 10, so that in the case of current conduction in the T+ bridge 134 or in the T− bridge 138, the magnetic fields then produced cancel each other out and a low-inductance connection is provided. The arrangement according to FIG. 10 comprises the power module 12, on the base 96 of which said semiconductor components 42 are arranged. The power module 12, in turn, is connected in thermally conductive fashion to the cooling surface 106 via the sintered layer 104 or alternatively via a flat solder/adhesive connection 110, in order to dissipate the operating heat.

The present invention is not limited to the embodiments described here and the aspects emphasized therein. Rather, a large number of modifications are possible within the range of the present invention, which are within the scope of the activities of a person skilled in the art.

1-11. (canceled)

12. A power module, comprising:
a circuit carrier which includes a carrier substrate and an electrical insulation layer, wherein the circuit carrier has a first conductor structure with an external contact region and at least one second conductor structure with at least one external contact region, and a further, third conductor structure which includes at least one external contact region;
semiconductor components arranged individually or in groups;
wherein contact faces arranged in a multifunctional frame assigned to the power module are electrically connected to the semiconductor components installed individually or in groups in the power module by solder connections with an inclusion of at least one spacer.

13. The power module according to claim 12, wherein the semiconductor components are arranged on a base of the power module individually or in groups.

14. The power module according to claim 12, wherein a first spacer of the at least one one spacer is arranged in a region of a joint between a bottom side of the multifunctional frame and a top side of the power module.

15. The power module according to claim 14, wherein a first solder connection of the solder connections is located in an opening on the bottom side of the multifunctional frame.

16. The power module according to claim 14, wherein a second spacer of the at least one spacer is arranged on a contact face of a semiconductor component.

17. The power module according to claim 16, wherein a second solder connection of the solder connections is made between the first spacer and the second spacer.

18. The power module according to claim 12, wherein the solder connections have a first solder layer and a second solder layer.

19. The power module according to claim 12, wherein the power module is connected to a cooling surface via a sintered layer or via a solder/adhesive connection.

20. The power module according to claim 12, wherein the semiconductor components and second spacers connected to them via contact faces are enclosed by a molding compound.

21. The power module according to claim 12, wherein the multifunctional frame is arranged above or below the power module, as seen in a Z direction.

22. The power module according to claim 12. wjereom current-conducting components including a T+ bridge and a T-bridge, are formed one above the other or next to each other in the multifunctional frame in such a way that a low-inductance connection is formed.
